(19) United States
(12) Patent Application Publication
(10) Pub. No.: US 2024/0263941 A1
(43) Pub. Date: Aug. 8, 2024

(54) INTENSITY IMBALANCE CALIBRATION ON AN OVERFILLED BIDIRECTIONAL MARK

(71) Applicant: ASML Netherlands B.V., Veldhoven (NL)

(72) Inventors: Rui CHENG, Wilton, CT (US); Joshua ADAMS, Wilton, CT (US); Franciscus Godefridus Casper BIJNEN, Valkenswaard (NL); Eric Brian CATEY, Danbury, CT (US); Igor Matheus Petronella AARTS, Port Chester, NY (US)

(73) Assignee: ASML Netherlands B.V., Veldhoven (NL)

(21) Appl. No.: 18/562,675

(22) PCT Filed: May 24, 2022
(86) PCT No.: PCT/EP2022/064102

§ 371 Date: Nov. 20, 2023

Related U.S. Application Data
(60) Provisional application No. 63/208,420, filed on Jun. 8, 2021.

(51) Int. Cl. G01B 11/27; G03F 9/00

(52) U.S. Cl. CPC G01B 11/272; G03F 9/7046; G03F 9/7065; G03F 9/7069; G03F 9/7076; G03F 9/7092

(57) ABSTRACT

Systems, apparatuses, and methods are provided for correcting the detected positions of alignment marks disposed on a substrate and aligning the substrate using the corrected data to accurately expose patterns on the substrate. An example method can include receiving a measurement signal including a combined intensity signal corresponding to first and second diffracted light beams diffracted from first and second alignment targets having different orientations. The example method can further include fitting the combined intensity signal using templates to determine weight values and determining, based on the templates and weight values, first and second intensity sub-signals corresponding to the first and second diffracted light beams. The method can further include determining first and second intensity imbalance signals based on the first and second intensity sub-signals and determining a set of corrections to the measurement signal based on the first and second intensity imbalance signals.

### CROSS-REFERENCE TO RELATED APPLICATIONS

This application claims priority of U.S. Provisional Patent Application No. 63/208,420, which was filed on Jun. 8, 2021, and which is incorporated herein in its entirety by reference.

### TECHNICAL FIELD

The present disclosure relates to metrology systems that may be used, for example, in a lithographic apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is interchangeably referred to as a mask or a reticle, can be used to generate a circuit pattern to be formed on an individual layer of the IC being formed. This pattern can be transferred onto a target portion (e.g., including part of, one, or several dies) on a substrate (e.g., a silicon wafer). Transfer of the pattern is typically via imaging onto a layer of radiation-sensitive material (e.g., resist) provided on the substrate. In general, a single substrate will contain a network of adjacent target portions that are successively patterned. Traditional lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel (e.g., opposite) to this scanning direction. It is also possible to transfer the pattern from the patterning device to the substrate by imprinting the pattern onto the substrate.

As semiconductor manufacturing processes continue to advance, the dimensions of circuit elements have continually been reduced while the amount of functional elements, such as transistors, per device has been steadily increasing over decades, following a trend commonly referred to as Moore's law. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Extreme ultraviolet (EUV) radiation, for example, electromagnetic radiation having wavelengths of around 50 nanometers (nm) or less (also sometimes referred to as soft x-rays), and including light at a wavelength of about 13.5 nm, can be used in or with a lithographic apparatus to produce extremely small features in or on substrates, for example, silicon wafers. A lithographic apparatus which uses EUV radiation having a wavelength within a range of 4 nm to 20 nm, for example 6.7 nm or 13.5 nm, can be used to form smaller features on a substrate than a lithographic apparatus which uses, for example, radiation with a wavelength of 193 nm.

Methods to produce EUV light include, but are not necessarily limited to, converting a material that has an element, for example, xenon (Xe), lithium (Li), or tin (Sn), with an emission line in the EUV range to a plasma state. For example, in one such method called laser produced plasma (LPP), the plasma can be produced by irradiating a target material, which is interchangeably referred to as fuel in the context of LPP sources, for example, in the form of a droplet, plate, tape, stream, or cluster of material, with an amplified light beam that can be referred to as a drive laser. For this process, the plasma is typically produced in a sealed vessel, for example, a vacuum chamber, and monitored using various types of metrology equipment.

During lithographic operation, different processing steps may require different layers to be sequentially formed on the substrate. Accordingly, it may be necessary to position the substrate relative to prior patterns formed thereon with a high degree of accuracy. Generally, alignment marks are placed on the substrate to be aligned and are located with reference to a second object. A lithographic apparatus may use a metrology system for detecting positions (e.g., X and Y positions) of the alignment marks and for aligning the substrate using the alignment marks to ensure accurate exposure from a mask. The metrology system may be used to determine a height of a wafer surface in the Z direction. However, any asymmetry present in the alignment marks can make it challenging to accurately align the substrate. Further, conventional alignment techniques may not be capable of removing unwanted effects due to alignment mark asymmetry.

### SUMMARY

The present disclosure describes various aspects of systems, apparatuses, and methods for correcting the detected positions of alignment targets disposed on a substrate, particularly when a spot size of the light used to detect the alignment targets at least partially overfills each of the alignment targets, such as is the case when the alignment targets include a combined bidirectional (CB) alignment mark. The present disclosure further describes various aspects of systems, apparatuses, and methods for aligning the substrate using the corrected data to ensure accurate exposure of one or more patterns on the substrate.

In some aspects, the present disclosure describes a metrology system. The metrology system can include an illumination system configured to generate and direct light to be diffracted from first and second alignment targets. The second alignment target can be oriented differently than the first alignment target. The metrology system can further include a detection system configured to receive first and second diffracted light beams diffracted from respective ones of the first and second alignment targets and to generate a measurement signal therefrom. The measurement signal can include a combined intensity signal including combined intensity values corresponding to the first and second diffracted light beams diffracted from the first and second alignment targets, respectively. The metrology system can further include a controller configured to fit the combined intensity signal using a set of templates to determine a set of weight values. The controller can be further configured to determine, based on the set of templates and the set of weight values, first and second intensity sub-signals including first and second intensity values corresponding to the first and second diffracted light beams. The controller can be further configured to determine first and second intensity imbalance signals based on the first and second intensity sub-signals. The controller can be further configured to determine a set of corrections (e.g., two corrections (X and Y) per color per polarization) to the measurement signal based on the first and second intensity imbalance signals.

In some aspects, the present disclosure describes a lithographic apparatus. The lithographic apparatus can include an illumination system configured to illuminate a pattern of a patterning device. The lithographic apparatus can further include a projection system configured to project an image of the pattern onto a target portion of a substrate. The lithographic apparatus can further include a metrology system. The metrology system can include an illumination subsystem configured to generate and direct light to be diffracted from first and second alignment targets. The second alignment target can be oriented differently than the first alignment target. The metrology system can further include a detection system configured to receive first and second diffracted light beams diffracted from respective ones of the first and second alignment targets and to generate a measurement signal therefrom. The measurement signal can include a combined intensity signal including combined intensity values corresponding to the first and second diffracted light beams diffracted from the first and second alignment targets, respectively. The metrology system can further include a controller configured to fit the combined intensity signal using a set of templates to determine a set of weight values. The controller can be further configured to determine, based on the set of templates and the set of weight values, first and second intensity sub-signals including first and second intensity values corresponding to the first and second diffracted light beams. The controller can be further configured to determine first and second intensity imbalance signals based on the first and second intensity sub-signals. The controller can be further configured to determine a set of corrections (e.g., two corrections (X and Y) per color per polarization) to the measurement signal based on the first and second intensity imbalance signals.

In some aspects, the present disclosure describes a method for correcting the detected positions of alignment marks disposed on a substrate. The method can include receiving a measurement signal that includes a combined intensity signal including combined intensity values corresponding to first and second diffracted light beams diffracted from first and second alignment targets, respectively. The second alignment target can be oriented differently than the first alignment target. The method can further include fitting the combined intensity signal using a set of templates to determine a set of weight values. The method can further include determining, based on the set of templates and the set of weight values, first and second intensity sub-signals including first and second intensity values corresponding to the first and second diffracted light beams. The method can further include determining first and second intensity imbalance signals based on the first and second intensity sub-signals. The method can further include determining a set of corrections (e.g., two corrections (X and Y) per color per polarization) to the measurement signal based on the first and second intensity imbalance signals.

Further features, as well as the structures and operations of various aspects, are described in detail below with reference to the accompanying drawings. It is noted that the disclosure is not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the aspects of this disclosure and to enable a person skilled in the relevant art(s) to make and use the aspects of this disclosure.

FIG. 1A is a schematic illustration of an example reflective lithographic apparatus according to some aspects of the present disclosure.

FIG. 1B is a schematic illustration of an example transmissive lithographic apparatus according to some aspects of the present disclosure.

FIG. 2 is a more detailed schematic illustration of the reflective lithographic apparatus shown in FIG. 1A according to some aspects of the present disclosure.

FIG. 3 is a schematic illustration of an example lithographic cell according to some aspects of the present disclosure.

FIG. 4 is a schematic illustration of a metrology system, according to some aspects of the present disclosure.

FIG. 5 is a schematic illustration of an example process flow for correcting the detected positions of alignment marks disposed on a substrate according to some aspects of the present disclosure.

FIG. 6 is a representation of an example combined bidirectional alignment mark according to some aspects of the present disclosure.

FIGS. 7A and 7B are representations of an example measurement signal according to some aspects of the present disclosure.

FIGS. 8A and 8B are representations of the intensity and phase components of an example measurement signal according to some aspects of the present disclosure.

FIG. 9 shows representations of example combined intensity signals of an example measurement signal according to some aspects of the present disclosure.

FIG. 10 is an example method for correcting the detected positions of alignment marks disposed on a substrate according to some aspects of the present disclosure or portion(s) thereof.

FIG. 11 is an example computer system for implementing some aspects of the present disclosure or portion(s) thereof.

The features and advantages of the present disclosure will become more apparent from the detailed description set forth below when taken in conjunction with the drawings, in which like reference characters identify corresponding elements throughout. In the drawings, unless otherwise indicated, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) merely describe the present disclosure. The scope of the disclosure is not limited to the disclosed embodiment(s). The breadth and scope of the disclosure are defined by the claims appended hereto and their equivalents.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

### Overview

In one example, ICs are built up layer by layer and can have 30 or more layers. On Product Overlay (OPO) is a measure of a lithographic apparatus's ability to fabricate these layers accurately on top of each other. Successive layers or multiple processes on the same layer must be accurately aligned to the previous layer. Otherwise, electrical contact between structures can be poor and the resulting devices may not perform to specification. Accurate alignment (e.g., decreased OPO error) can increase device yield and enable smaller product patterns to be fabricated.

Process-induced wafer errors arising from the complexity of the patterns, as well as the quantity of patterned layers, can be a main contributor to (OPO) errors. For example, wafer alignment errors resulting from horizontal (e.g., X, Y, Rz) alignment of wafers before they are exposed can be a predominate source of OPO error and, in some instances, contribute to roughly half of the OPO errors for a particular technology node. These OPO errors can have relatively high spatial variations from wafer to wafer as well as within each wafer.

Process-induced wafer errors can be mitigated by measuring the relative position of several alignment marks within a field to reduce OPO errors. Alignment error variations within the field can be used in a regression model to correct OPO errors within the field. Process-induced wafer errors can be further mitigated by measuring the relative positions of several alignment marks within a particular measurement field. For example, alignment error variation within the field can be used to fit a model to correct for OPO within the field. The OPO error between successive layers formed in or on the patterned substrate can be controlled by various parts of the exposure system of the lithographic apparatus as described in greater detail below.

In order to control a lithographic process to place device features accurately on the substrate, one or more diffraction targets (e.g., alignment marks) can be provided on the substrate, and the lithographic apparatus can include one or more alignment sensors (e.g., forming a position measuring apparatus) configured to measure the positions of the one or more diffraction targets. Additionally, a fringe pattern can be formed by two off-axis coherent beams of an alignment sensor to provide structured illumination, which can act as a projected reference grating to investigate diffraction target asymmetry and substantially eliminate the need for a separate physical reference grating.

A lithographic apparatus can include one or more alignment systems configured to measure the position of the diffraction target and align the substrate with respect to the lithographic apparatus. For example, the data can be obtained using a SMart Alignment Sensor Hybrid (SMASH) sensor that employs a self-referencing interferometer with a single detector and four different wavelengths, and extracts the alignment signal in software. An example SMASH sensor is described in, for example, U.S. Pat. No. 6,961,116, issued Nov. 1, 2005, and titled “Lithographic Apparatus, Device Manufacturing Method, and Device Manufactured Thereby,” which is hereby incorporated by reference in its entirety. In another example, the data can be obtained using an Advanced Technology using High order ENhancement of Alignment (ATHENA) sensor that directs each of seven diffraction orders to a dedicated detector. An example ATHENA sensor is described in, for example, U.S. Pat. No. 6,297,876, issued Oct. 2, 2001, and titled “Lithographic Projection Apparatus with an Alignment System for Aligning Substrate on Mask,” which is hereby incorporated by reference in its entirety.

In yet another example, an alignment system can include a self-referencing interferometer configured to produce two overlapping images of an alignment mark, rotate these two overlapping images over 180 degrees with respect to each other, and detect the intensity variation of the interfering Fourier transforms of these two overlapping images in a pupil plane. These intensity variations can correspond to a phase difference between different diffraction orders of the two overlapping images. The self-referencing interferometer can derive phase difference positional information from this phase difference for use in the alignment process. Example alignment systems that include self-referencing interferometers are described in, for example, European Patent No. EP 1 372 040, granted Mar. 5, 2008, and titled “Lithographic Apparatus and Device Manufacturing Method,” and U.S. Pat. No. 8,610,898, issued Dec. 17, 2013, and titled “Self-Referencing Interferometer, Alignment System, and Lithographic Apparatus,” each of which is hereby incorporated by reference in its entirety.

Additionally, measurement of a plurality of alignment marks can enable modeling and correction of intra-field distortion. For example, parallel-wafer alignment systems can be implemented to enable correction of intra-field distortion without substantially impacting overall throughput. These parallel-wafer alignment systems can utilize interferometry and multi-mode interference (MMI) to measure the position of the diffraction target and align the substrate with respect to the lithographic apparatus. Example parallel-wafer alignment systems are described in, for example, U.S. Provisional Patent Application No. 62/724,198, filed Aug. 29, 2018, and titled “Compact Alignment Sensor Arrangements,” and U.S. Provisional Patent Application No. 62/877,964, filed Jul. 24, 2019, and titled “On Chip Wafer Alignment Sensor,” each of which is hereby incorporated by reference in its entirety.

However, these and other alignment systems and techniques can be subject to certain drawbacks and limitations. For example, alignment marks can suffer from asymmetry that can appear as false wafer deformation data causing the lithographic apparatus to print a new layer at the wrong position and cause OPO error. There are many types of alignment mark asymmetry, such as side wall angle, floor tilt, top tilt, critical dimension (CD) imbalance, and the like. The effect of alignment mark asymmetry is also a function of the alignment mark design (e.g., pitch, subsegmentation) and the stack of layers placed above and below and alignment mark. But in general all these situations create a wavelength (2) and polarization dependent signal while a symmetric mark will return the same phase determined position for all color (e.g., wavelength) and polarization signals.

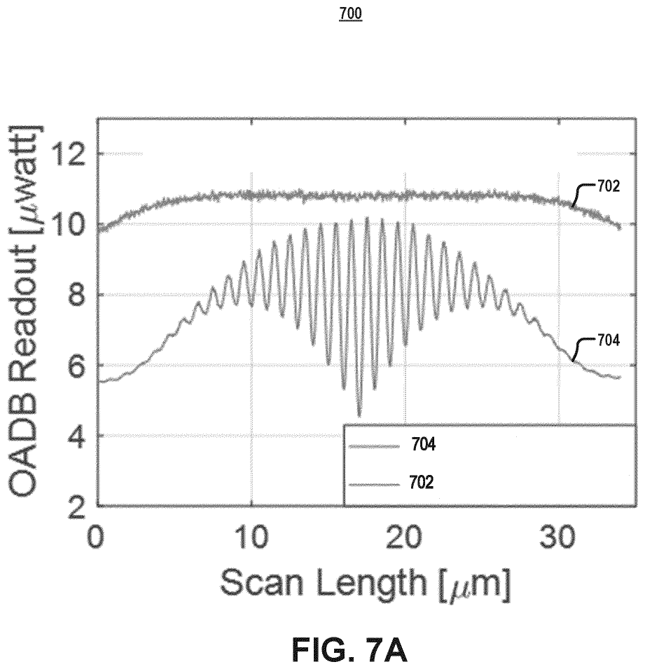

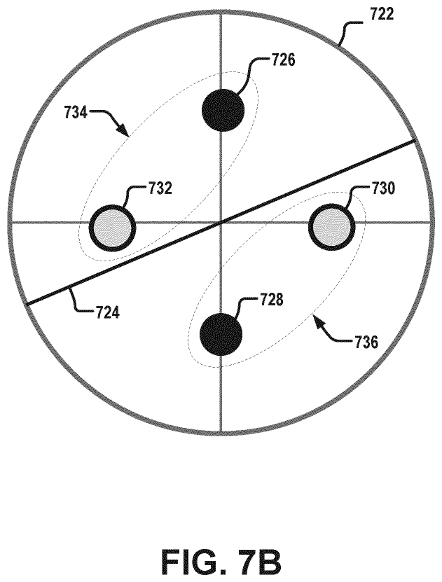

In some aspects, these and other alignment systems and techniques can use multi-color and polarization alignment sensor signals (e.g., 12 colors and 2 polarizations) to calibrate out the effects of alignment mark asymmetries based on intensity traces (e.g., not subjected to interference or interferometry) detected by an intensity channel and phase traces (e.g., subjected to interference and/or interferometry) detected by a phase channel. The intensity channel can be developed to measure a normalized intensity imbalance Q to calibrate the position error due to alignment mark asymmetry. However, as shown in FIG. 7B, an example fixed-pupil divider of the intensity channel can determine that only two intensity signals can be detected by sensor simultaneously. This may not create a problem for example bidirectional marks that are considerably larger than the illumination spot. When the intensity channel scans these large bidirectional marks, the signals from different gratings and orders will be collected separately and sequentially. However, problems may arise when the intensity channel scans bidirectional marks and detects both segments simultaneously, such as the CB alignment mark shown in FIG. 6. Because the illumination spot monitors, detects, and/or registers (referred to herein generally as “overfills”) both gratings, the signals detected by the sensor from the different gratings and orders will be mixed. Since the intensity signal per grating per order may be unknown, the Q values cannot be calculated using existing techniques and thus the asymmetry of each grating cannot be calibrated directly.

Accordingly, there is a need for a metrology system that can separate the combined intensity signals from different gratings and orders when the intensity channel scans bidirectional marks having multiple alignment targets and detects those alignment targets simultaneously.

In contrast, some aspects of the present disclosure can provide systems, apparatuses, methods, and computer program products for separating the combined intensity signals from different gratings and orders when the intensity channel scans bidirectional marks having two non-parallel target fields that are detected simultaneously. In some aspects, the present disclosure provides Trace Template Fit (TTF) technique that uses the phase channel signals as a template to fit the mixed intensity signal so that the intensity signal from individual gratings can be recovered and the intensity imbalance Q can be calculated.

There are many exemplary aspects to the systems, apparatuses, methods, and computer program products disclosed herein. For example, aspects of the present disclosure can separate the X and Y positive and negative first order diffraction intensity signals diffracted from small bidirectional alignment marks to improve the measurement accuracy and reduce the time and computing costs (e.g., central processing unit (CPU), memory, etc.) required to correct measured alignment mark positions.

Before describing such aspects in more detail, however, it is instructive to present an example environment in which aspects of the present disclosure can be implemented.

### Example Lithographic Systems

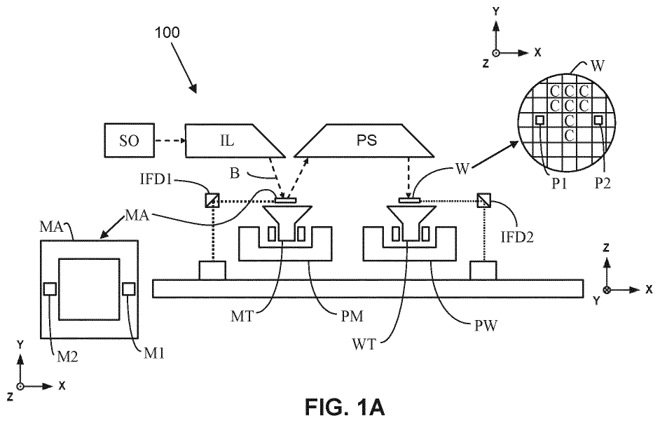

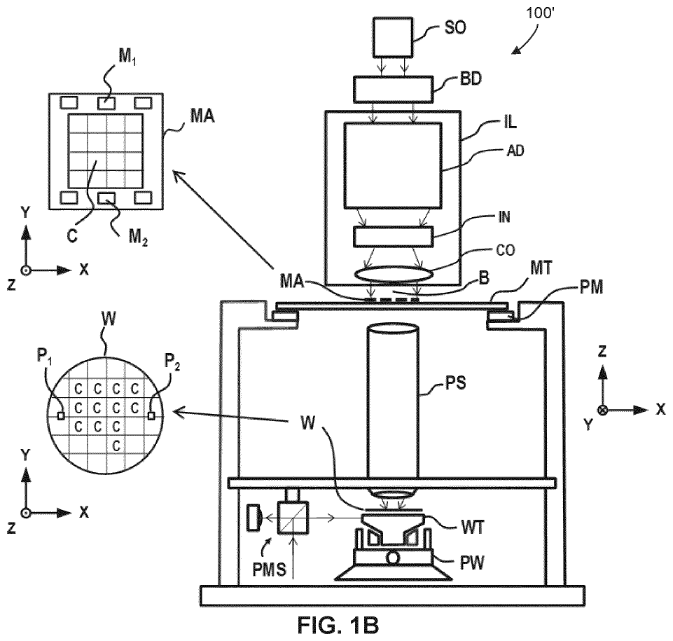

FIGS. 1A and 1B are schematic illustrations of a lithographic apparatus 100 and a lithographic apparatus 100′, respectively, in which aspects of the present disclosure can be implemented. As shown in FIGS. 1A and 1B, the lithographic apparatuses 100 and 100′ are illustrated from a point of view (e.g., a side view) that is normal to the XZ plane (e.g., the X-axis points to the right, the Z-axis points upward, and the Y-axis points into the page away from the viewer), while the patterning device MA and the substrate W are presented from additional points of view (e.g., a top view) that are normal to the XY plane (e.g., the X-axis points to the right, the Y-axis points upward, and the Z-axis points out of the page toward the viewer).

In some aspects, the lithographic apparatus 100 and/or the lithographic apparatus 100′ can include one or more of the following structures: an illumination system IL (e.g., an illuminator) configured to condition a radiation beam B (e.g., a deep ultra violet (DUV) radiation beam or an extreme ultra violet (EUV) radiation beam); a support structure MT (e.g., a mask table) configured to support a patterning device MA (e.g., a mask, a reticle, or a dynamic patterning device) and connected to a first positioner PM configured to accurately position the patterning device MA; and, a substrate holder such as a substrate table WT (e.g., a wafer table) configured to hold a substrate W (e.g., a resist-coated wafer) and connected to a second positioner PW configured to accurately position the substrate W. Lithographic apparatuses 100 and 100′ also have a projection system PS (e.g., a refractive projection lens system) configured to project a pattern imparted to the radiation beam B by patterning device MA onto a target portion C (e.g., a portion including one or more dies) of the substrate W. In lithographic apparatus 100, the patterning device MA and the projection system PS are reflective. In lithographic apparatus 100′, the patterning device MA and the projection system PS are transmissive.

In some aspects, in operation, the illumination system IL can receive a radiation beam from a radiation source SO (e.g., via a beam delivery system BD shown in FIG. 1B). The illumination system IL can include various types of optical structures, such as refractive, reflective, catadioptric, magnetic, electromagnetic, electrostatic, and other types of optical components, or any combination thereof, for directing, shaping, or controlling radiation. In some aspects, the illumination system IL can be configured to condition the radiation beam B to have a desired spatial and angular intensity distribution in its cross-section at a plane of the patterning device MA.

In some aspects, the support structure MT can hold the patterning device MA in a manner that depends on the orientation of the patterning device MA with respect to a reference frame, the design of at least one of the lithographic apparatuses 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

In some aspects, the patterning device MA can be transmissive (as in lithographic apparatus 100′ of FIG. 1B) or reflective (as in lithographic apparatus 100 of FIG. 1A). The patterning device MA can include various structures such as reticles, masks, programmable mirror arrays, programmable LCD panels, other suitable structures, or combinations thereof. Masks can include mask types such as binary, alternating phase shift, or attenuated phase shift, as well as various hybrid mask types. In one example, a programmable mirror array can include a matrix arrangement of small mirrors, each of which can be individually tilted so as to reflect an incoming radiation beam in different directions. The tilted mirrors can impart a pattern in the radiation beam B, which is reflected by a matrix of small mirrors.

The term “projection system” PS should be interpreted broadly and can encompass any type of projection system, including refractive, reflective, catadioptric, magnetic, anamorphic, electromagnetic, and electrostatic optical systems, or any combination thereof, as appropriate for the exposure radiation being used, and/or for other factors such as the use of an immersion liquid (e.g., on the substrate W) or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps. In addition, any use herein of the term “projection lens” can be interpreted, in some aspects, as synonymous with the more general term “projection system” PS.

In some aspects, the lithographic apparatus 100 and/or the lithographic apparatus 100″ can be of a type having two (e.g., “dual stage”) or more substrate tables WT and/or two or more mask tables). In such “multiple stage” machines, the additional substrate tables WT can be used in parallel, or preparatory steps can be carried out on one or more tables while one or more other substrate tables WT are being used for exposure. In one example, steps in preparation of a subsequent exposure of the substrate W can be carried out on the substrate W located on one of the substrate tables WT while another substrate W located on another of the substrate tables WT is being used for exposing a pattern on another substrate W. In some aspects, the additional table may not be a substrate table WT.

In some aspects, in addition to the substrate table WT, the lithographic apparatus 100 and/or the lithographic apparatus 100′ can include a measurement stage. The measurement stage can be arranged to hold a sensor. The sensor can be arranged to measure a property of the projection system PS, a property of the radiation beam B, or both. In some aspects, the measurement stage can hold multiple sensors. In some aspects, the measurement stage can move beneath the projection system PS when the substrate table WT is away from the projection system PS.

In some aspects, the lithographic apparatus 100 and/or the lithographic apparatus 100′ can also be of a type wherein at least a portion of the substrate can be covered by a liquid having a relatively high refractive index, e.g., water, so as to fill a space between the projection system PS and the substrate W. An immersion liquid can also be applied to other spaces in the lithographic apparatus, for example, between the patterning device MA and the projection system PS. Immersion techniques provide for increasing the numerical aperture of projection systems. The term “immersion” as used herein does not mean that a structure, such as a substrate, must be submerged in liquid, but rather only means that liquid is located between the projection system and the substrate during exposure. Various immersion techniques are described in U.S. Pat. No. 6,952,253, issued Oct. 4, 2005, and titled “LITHOGRAPHIC APPARATUS AND DEVICE MANUFACTURING METHOD,” which is incorporated by reference herein in its entirety.

Referring to FIGS. 1A and 1B, the illumination system IL receives a radiation beam B from a radiation source SO. The radiation source SO and the lithographic apparatus 100 or 100′ can be separate physical entities, for example, when the radiation source SO is an excimer laser. In such cases, the radiation source SO is not considered to form part of the lithographic apparatus 100 or 100′, and the radiation beam B passes from the radiation source SO to the illumination system IL with the aid of a beam delivery system BD (e.g., shown in FIG. 1B) including, for example, suitable directing mirrors and/or a beam expander. In other cases, the radiation source SO can be an integral part of the lithographic apparatus 100 or 100′, for example, when the radiation source SO is a mercury lamp. The radiation source SO and the illuminator IL, together with the beam delivery system BD, if required, can be referred to as a radiation system.

In some aspects, the illumination system IL can include an adjuster AD for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illumination system IL can include various other components, such as an integrator IN and a radiation collector CO (e.g., a condenser or collector optic). In some aspects, the illumination system IL can be used to condition the radiation beam B to have a desired uniformity and intensity distribution in its cross section.

Referring to FIG. 1A, in operation, the radiation beam B can be incident on the patterning device MA (e.g., a mask, reticle, programmable mirror array, programmable LCD panel, any other suitable structure or combination thereof), which can be held on the support structure MT (e.g., a mask table), and can be patterned by the pattern (e.g., design layout) present on the patterning device MA. In lithographic apparatus 100, the radiation beam B can be reflected from the patterning device MA. Having traversed (e.g., after being reflected from) the patterning device MA, the radiation beam B can pass through the projection system PS, which can focus the radiation beam B onto a target portion C of the substrate W or onto a sensor arranged at a stage.

In some aspects, with the aid of the second positioner PW and position sensor IFD2 (e.g., an interferometric device, linear encoder, or capacitive sensor), the substrate table WT can be moved accurately, e.g., so as to position different target portions C in the path of the radiation beam B. Similarly, the first positioner PM and another position sensor IFD1 (e.g., an interferometric device, linear encoder, or capacitive sensor) can be used to accurately position the patterning device MA with respect to the path of the radiation beam B.

In some aspects, patterning device MA and substrate W can be aligned using mask alignment marks M1 and M2 and substrate alignment marks P1 and P2. Although FIGS. 1A and 1B illustrate the substrate alignment marks P1 and P2 as occupying dedicated target portions, the substrate alignment marks P1 and P2 may be located in spaces between target portions. Substrate alignment marks P1 and P2 are referred to as scribe-lane alignment marks when they are located between the target portions C. Substrate alignment marks P1 and P2 can also be arranged in the target portion C area as in-die marks. These in-die marks can also be used as metrology marks, for example, for overlay measurements.

In some aspects, for purposes of illustration and not limitation, one or more of the figures herein can utilize a Cartesian coordinate system. The Cartesian coordinate system includes three axes: an X-axis; a Y-axis; and a Z-axis. Each of the three axes is orthogonal to the other two axes (e.g., the X-axis is orthogonal to the Y-axis and the Z-axis, the Y-axis is orthogonal to the X-axis and the Z-axis, the Z-axis is orthogonal to the X-axis and the Y-axis). A rotation around the X-axis is referred to as an Rx-rotation. A rotation around the Y-axis is referred to as an Ry-rotation. A rotation around about the Z-axis is referred to as an Rz-rotation. In some aspects, the X-axis and the Y-axis define a horizontal plane, whereas the Z-axis is in a vertical direction. In some aspects, the orientation of the Cartesian coordinate system may be different, for example, such that the Z-axis has a component along the horizontal plane. In some aspects, another coordinate system, such as a cylindrical coordinate system, can be used.

Referring to FIG. 1B, the radiation beam B is incident on the patterning device MA, which is held on the support structure MT, and is patterned by the patterning device MA. Having traversed the patterning device MA, the radiation beam B passes through the projection system PS, which focuses the beam onto a target portion C of the substrate W. In some aspects, the projection system PS can have a pupil conjugate to an illumination system pupil. In some aspects, portions of radiation can emanate from the intensity distribution at the illumination system pupil and traverse a mask pattern without being affected by diffraction at the mask pattern MP and create an image of the intensity distribution at the illumination system pupil.

The projection system PS projects an image MP′ of the mask pattern MP, where image MP′ is formed by diffracted beams produced from the mask pattern MP by radiation from the intensity distribution, onto a resist layer coated on the substrate W. For example, the mask pattern MP can include an array of lines and spaces. A diffraction of radiation at the array and different from zeroth-order diffraction generates diverted diffracted beams with a change of direction in a direction perpendicular to the lines. Reflected light (e.g., zeroth-order diffracted beams) traverses the pattern without any change in propagation direction. The zeroth-order diffracted beams traverse an upper lens or upper lens group of the projection system PS, upstream of the pupil conjugate of the projection system PS, to reach the pupil conjugate. The portion of the intensity distribution in the plane of the pupil conjugate and associated with the zeroth-order diffracted beams is an image of the intensity distribution in the illumination system pupil of the illumination system IL. In some aspects, an aperture device can be disposed at, or substantially at, a plane that includes the pupil conjugate of the projection system PS.

The projection system PS is arranged to capture, by means of a lens or lens group, not only the zeroth-order diffracted beams, but also first-order or first- and higher-order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the substrate W to create an image of the mask pattern MP at highest possible resolution and process window (e.g., usable depth of focus in combination with tolerable exposure dose deviations). In some aspects, astigmatism aberration can be reduced by providing radiation poles (not shown) in opposite quadrants of an illumination system pupil. Further, in some aspects, astigmatism aberration can be reduced by blocking the zeroth-order beams in the pupil conjugate of the projection system PS associated with radiation poles in opposite quadrants. This is described in more detail in U.S. Pat. No. 7,511,799, issued Mar. 31, 2009, and titled “LITHOGRAPHIC PROJECTION APPARATUS AND A DEVICE MANUFACTURING METHOD,” which is incorporated by reference herein in its entirety.

In some aspects, with the aid of the second positioner PW and a position measurement system PMS (e.g., including a position sensor such as an interferometric device, linear encoder, or capacitive sensor), the substrate table WT can be moved accurately, e.g., so as to position different target portions C in the path of the radiation beam B at a focused and aligned position. Similarly, the first positioner PM and another position sensor (e.g., an interferometric device, linear encoder, or capacitive sensor) (not shown in FIG. 1B) can be used to accurately position the patterning device MA with respect to the path of the radiation beam B (e.g., after mechanical retrieval from a mask library or during a scan). Patterning device MA and substrate W can be aligned using mask alignment marks M1 and M2 and substrate alignment marks P1 and P2.

In general, movement of the support structure MT can be realized with the aid of a long-stroke positioner (coarse positioning) and a short-stroke positioner (fine positioning), which form part of the first positioner PM. Similarly, movement of the substrate table WT can be realized using a long-stroke positioner and a short-stroke positioner, which form part of the second positioner PW. In the case of a stepper (as opposed to a scanner), the support structure MT can be connected to a short-stroke actuator only or can be fixed. Patterning device MA and substrate W can be aligned using mask alignment marks M1 and M2, and substrate alignment marks P1 and P2. Although the substrate alignment marks (as illustrated) occupy dedicated target portions, they can be located in spaces between target portions (e.g., scribe-lane alignment marks). Similarly, in situations in which more than one die is provided on the patterning device MA, the mask alignment marks M1 and M2 can be located between the dies.

Support structure MT and patterning device MA can be in a vacuum chamber V, where an in-vacuum robot can be used to move patterning devices such as a mask in and out of vacuum chamber. Alternatively, when support structure MT and patterning device MA are outside of the vacuum chamber, an out-of-vacuum robot can be used for various transportation operations, similar to the in-vacuum robot. In some instances, both the in-vacuum and out-of-vacuum robots need to be calibrated for a smooth transfer of any payload (e.g., a mask) to a fixed kinematic mount of a transfer station.

In some aspects, the lithographic apparatuses 100 and 100′ can be used in at least one of the following modes:
1. In step mode, the support structure MT and the substrate table WT are kept essentially stationary, while an entire pattern imparted to the radiation beam B is projected onto a target portion C at one time (e.g., a single static exposure). The substrate table WT is then shifted in the X and/or Y direction so that a different target portion C can be exposed.
2. In scan mode, the support structure MT and the substrate table WT are scanned synchronously while a pattern imparted to the radiation beam B is projected onto a target portion C (e.g., a single dynamic exposure). The velocity and direction of the substrate table WT relative to the support structure MT (e.g., mask table) can be determined by the (de-)magnification and image reversal characteristics of the projection system PS.
3. In another mode, the support structure MT is kept substantially stationary holding a programmable patterning device MA, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device MA, such as a programmable mirror array.

In some aspects, the lithographic apparatuses 100 and 100′ can employ combinations and/or variations of the above-described modes of use or entirely different modes of use.

In some aspects, as shown in FIG. 1A, the lithographic apparatus 100 can include an EUV source configured to generate an EUV radiation beam B for EUV lithography. In general, the EUV source can be configured in a radiation source SO, and a corresponding illumination system IL can be configured to condition the EUV radiation beam B of the EUV source.

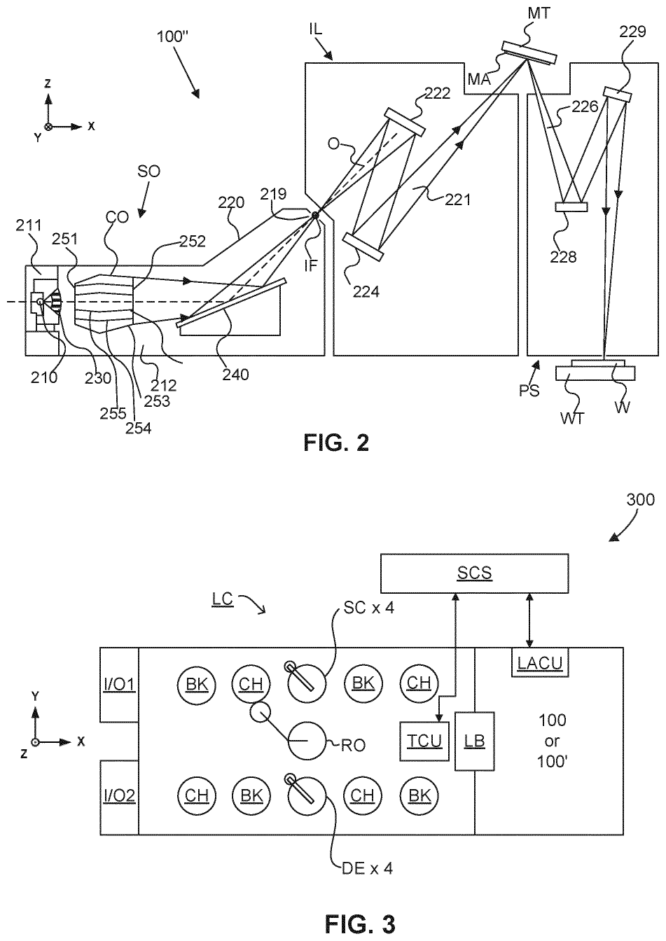

FIG. 2 shows the lithographic apparatus 100 in more detail, including the radiation source SO (e.g., a source collector apparatus), the illumination system IL, and the projection system PS. As shown in FIG. 2, the lithographic apparatus 100 is illustrated from a point of view (e.g., a side view) that is normal to the XZ plane (e.g., the X-axis points to the right and the Z-axis points upward).

The radiation source SO is constructed and arranged such that a vacuum environment can be maintained in an enclosing structure 220. The radiation source SO includes a source chamber 211 and a collector chamber 212 and is configured to produce and transmit EUV radiation. EUV radiation can be produced by a gas or vapor, for example xenon (Xe) gas, lithium (Li) vapor, or tin (Sn) vapor in which an EUV radiation emitting plasma 210 is created to emit radiation in the EUV range of the electromagnetic spectrum. The EUV radiation emitting plasma 210, at least partially ionized, can be created by, for example, an electrical discharge or a laser beam. Partial pressures of, for example, about 10.0 pascals (Pa) of Xe gas, Li vapor, Sn vapor, or any other suitable gas or vapor can be used for efficient generation of the radiation. In some aspects, a plasma of excited tin is provided to produce EUV radiation.

The radiation emitted by the EUV radiation emitting plasma 210 is passed from the source chamber 211 into the collector chamber 212 via an optional gas barrier or contaminant trap 230 (e.g., in some cases also referred to as contaminant barrier or foil trap), which is positioned in or behind an opening in the source chamber 211. The contaminant trap 230 can include a channel structure. Contaminant trap 230 can also include a gas barrier or a combination of a gas barrier and a channel structure. The contaminant trap 230 further indicated herein at least includes a channel structure.

The collector chamber 212 can include a radiation collector CO (e.g., a condenser or collector optic), which can be a so-called grazing incidence collector. Radiation collector CO has an upstream radiation collector side 251 and a downstream radiation collector side 252. Radiation that traverses radiation collector CO can be reflected off a grating spectral filter 240 to be focused in a virtual source point IF. The virtual source point IF is commonly referred to as the intermediate focus, and the source collector apparatus is arranged such that the virtual source point IF is located at or near an opening 219 in the enclosing structure 220. The virtual source point IF is an image of the EUV radiation emitting plasma 210. The grating spectral filter 240 can be used to suppress infrared (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the radiation beam 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination system IL and projection system PS. Optionally, the grating spectral filter 240 can be present depending upon the type of lithographic apparatus. Further, there can be more mirrors present than those shown in the FIG. 2. For example, there can be one to six additional reflective elements present in the projection system PS than shown in FIG. 2.

Radiation collector CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a radiation collector CO of this type is preferably used in combination with a discharge produced plasma (DPP) source.

### Example Lithographic Cell

FIG. 3 shows a lithographic cell 300, also sometimes referred to a lithocell or cluster. As shown in FIG. 3, the lithographic cell 300 is illustrated from a point of view (e.g., a top view) that is normal to the XY plane (e.g., the X-axis points to the right and the Y-axis points upward).

Lithographic apparatus 100 or 100′ can form part of lithographic cell 300. Lithographic cell 300 can also include one or more apparatuses to perform pre- and post-exposure processes on a substrate. For example, these apparatuses can include spin coaters SC to deposit resist layers, developers DE to develop exposed resist, chill plates CH, and bake plates BK. A substrate handler RO (e.g., a robot) picks up substrates from input/output ports I/O1 and I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Metrology System

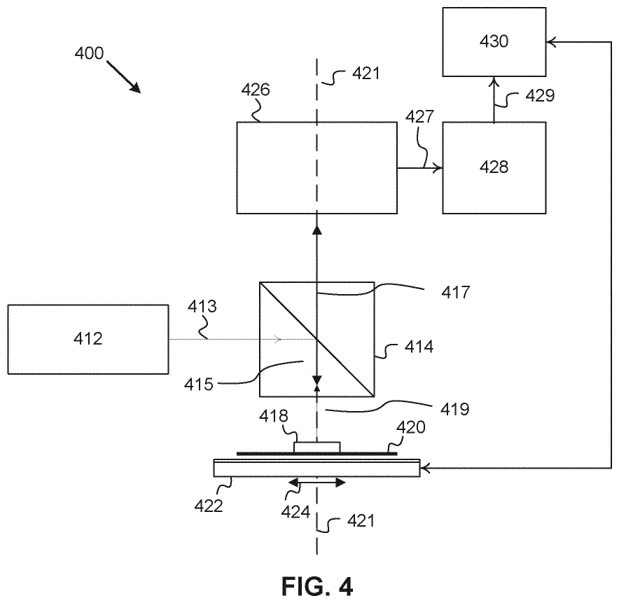

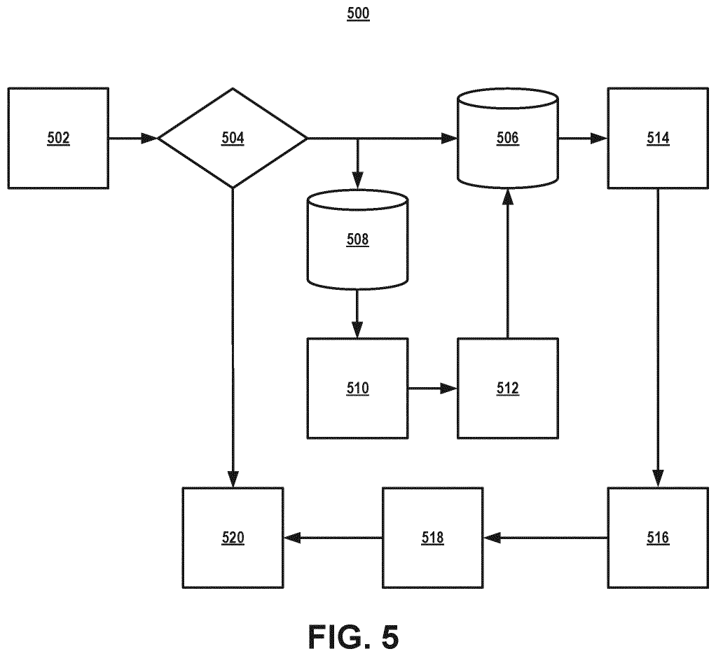

FIG. 4 illustrates a schematic of a cross-sectional view of a metrology system 400 that can be implemented as a part of lithographic apparatus 100 or 100′, according to an embodiment. In an example of this embodiment, metrology system 400 may be configured to align a substrate (e.g., substrate W) with respect to a patterning device (e.g., patterning device MA). Metrology system 400 may be further configured to detect positions of alignment marks on the substrate and to align the substrate with respect to the patterning device or other components of lithography apparatus 100 or 100′ using the detected positions of the alignment marks. Such alignment of the substrate may ensure accurate exposure of one or more patterns on the substrate.

According to an embodiment, metrology system 400 may include an illumination system 412, a reflector 414, an interferometer 426, a detector 428, and a controller 430, according an example of this embodiment. Illumination system 412 may be configured to provide a radiation beam 413. Radiation beam 413 may include, for example, an electromagnetic narrow band having one or more passbands. In another example, the one or more passbands may be discrete narrow passbands within a spectrum of wavelengths between about 500 nm to about 900 nm. Illumination system 412 may be further configured to provide one or more passbands having substantially constant center wavelength (CWL) values over a long period of time (e.g., over a lifetime of illumination system 412). Such configuration of illumination system 412 may help to prevent the shift of the actual CWL values from the desired CWL values, as discussed above, in current metrology systems. And, as a result, the use of constant CWL values may increase long-term stability and accuracy of metrology systems (e.g., metrology system 400) compared to the current metrology systems.

Reflector 414 may be configured to receive radiation beam 413 and direct radiation beam 413 towards substrate 420 as radiation beam 415, according an embodiment. Reflector 414 may be a beam splitter, a mirror, or a dichromatic mirror. In one example, stage 422 is moveable along direction 424. Radiation beam 415 may be configured to illuminate a plurality of alignment marks 418 or targets located on substrate 420. In another example, radiation beam 415 is configured to reflect from a surface of substrate 420. The plurality of alignment marks 418 may be coated with a radiation sensitive film in an example of this embodiment. In another example, the plurality of alignment marks 418 may have one hundred and eighty degree symmetry. That is, when one alignment mark in the plurality of alignment marks 418 is rotated one hundred and eighty degrees about an axis of symmetry perpendicular to a plane of another alignment mark in the plurality of alignment marks 418, the rotated alignment mark may be substantially identical to the un-rotated alignment mark.

As illustrated in FIG. 4, one or more radiation beams 419 may be diffracted from the plurality of alignment marks 418, or reflected from a surface of substrate 420, and received at interferometer 426 as one or more radiation beams 417. Interferometer 426 comprises any appropriate set of optical-elements, for example, a combination of prisms that may be configured to form two images of the plurality of alignment marks 418 based on the received one or more radiation beams 417. It should be appreciated that a good quality image need not be formed, but that the features of the plurality of alignment marks 418 should be resolved. Interferometer 426 may be further configured to rotate one of the two images with respect to the other of the two images one hundred and eighty degrees and recombine the two images interferometrically.

In an embodiment, detector 428 may be configured to receive the recombined image and detect an interference as a result of the recombined image when alignment axis 421 of metrology system 400 passes through a center of symmetry (not shown) of the plurality of alignment marks 418. Such interference may be due to the plurality of alignment marks 418 being one hundred and eighty degree symmetrical, and the recombined image interfering constructively or destructively, according to an example embodiment. Based on the detected interference, detector 428 may be further configured to determine a position of the center of symmetry of the plurality of alignment marks 418 and consequently, detect a position of substrate 420. According to an example, alignment axis 421 may be aligned with an optical beam perpendicular to substrate 420 and passing through a center of image rotation interferometer 426. In another example, detector 428 is configured to receive the recombined image and detect an interference of light being reflected off a surface of substrate 420.

In a further embodiment, controller 430 may be configured to receive a measurement signal 429 including measurement data. Measurement data can include, but is not limited to, electronic information indicative of the determined center of symmetry. Controller 430 may be further configured to determine a position of stage 422 and correlate the position of stage 422 with the position of the center of symmetry of the plurality of alignment marks 418. As such, the positions of the plurality of alignment marks 418 and consequently, the position of substrate 420 may be accurately determined with reference to stage 422. Alternatively, controller 430 may be configured to determine a position of metrology system 400 or any other reference element such that the center of symmetry of the plurality of alignment marks 418 may be determined with reference to metrology system 400 or any other reference element.

In an embodiment, controller 430 can be configured to apply a correction to a measurement received from detector 428 to account for asymmetry that can exist in the plurality of alignment marks 418. The asymmetry can exist due to imperfections in the structure of the mark itself (e.g., sidewall angle, critical dimension spacing, etc.) or due to non-linear optical effects based on the wavelength of light being directed towards the plurality of alignment marks 418.

It should be noted that even though reflector 414 is shown to direct radiation beam 413 towards the plurality of alignment marks 418 as radiation beam 415, the disclosure is not so limiting. It would be apparent to a person skilled in the relevant art that other optical arrangements may be used to obtain the similar result of illuminating the plurality of alignment marks 418 on substrate 420 and detecting an image of the plurality of alignment marks 418. Reflector 414 may direct the illumination in a direction normal to the surface of substrate 420, or at an angle.

As a foundation for some aspects, the metrology system 400 can include an illumination system 412 configured to generate a radiation beam 413. In some aspects, the radiation beam 413 generated by the illumination system 412 can include a plurality of wavelengths (e.g., colors), a plurality of polarization phases, or a combination thereof. The metrology system 400 can further include a reflector 414 configured to direct the radiation beam 413 towards a substrate 420 (e.g., in the form of radiation beam 415). The metrology system 400 can further include an interferometer 426 configured to receive one or more radiation beams 417 diffracted from a plurality of alignment marks 418 disposed on the substrate 420 or reflected from the substrate 420 (e.g., in the form of one or more radiation beams 419). The interferometer 426 can be further configured to generate one or more output radiation beams 427 from an interference between the diffracted or reflected one or more radiation beams 417.

The metrology system 400 can further include a detector 428. In some aspects, the detector 428 can include an optical analog to digital board (OADB). The detector 428 can be configured to receive the one or more output radiation beams 427 from the interferometer 426. The detector 428 can be further configured to generate a measurement signal 429 based on the received one or more output radiation beams 427.

In some aspects, the plurality of alignment marks 418 can include first and second alignment targets having non-parallel patterns (e.g., a pattern of the first alignment target is not oriented parallel to a pattern of the second alignment target), and the measurement signal 429 can include a combined intensity signal that includes combined intensity values corresponding to the first and second diffracted light beams diffracted from the first and second alignment targets, respectively. The intensity channels are not depicted in FIG. 4 for the sake of brevity. In some aspects, after reflector 414 and before the interferometer 426, another reflector or beam splitter can be positioned to direct the one or more radiation beams 417 to an intensity channel detection unit. As a result, the measurement signal 429 may not contain the intensity signal and sub-signals which are used by the controller 430 to correct for the alignment mark asymmetries as described herein. In some aspects, the measurement signal 429 received by the controller 430 can be used to create the templates for the intensity signals. In some aspects, the controller 430 can measure the intensities, but these intensities are combined positive and negative diffraction order signals. Accordingly, the measured intensities are not desirable for detecting the intensity imbalance between the positive and negative diffraction orders. Yet detecting this intensity imbalance is, in some aspects, required to correct for the alignment mark asymmetry impacting the position derived from the phase channels as described herein.

In some aspects, the measurement signal 429 can further include a combined phase signal comprising combined phase values corresponding to the first and second diffracted light beams. In some aspects, the detector 428 can be configured to receive the first and second diffracted light beams and generate the combined intensity signal and the combined phase signal.

The metrology system 400 can further include a controller 430 configured to fit the combined intensity signal using a set of templates to determine a set of weight values. In one example, the controller 430 can be configured to generate the set of templates based on the combined phase signal. In another example, the controller 430 can be configured to generate the set of templates based on a simulation. In yet another example, the set of templates can include first and second subsets of templates corresponding to the first and second alignment targets, respectively, and the controller 430 can be configured to model the combined intensity signal as a weighted sum of the first and second subsets of templates. In still another example, the set of templates can include intensity signal templates, and the controller 430 can be configured to determine the set of templates using a TTF machine learning model trained on measurements associated with alignment marks by a process that includes (i) fitting the intensity signal templates on each of the measurements and (ii) refitting the fitted intensity signal templates for each of the alignment marks to generate modified intensity signal templates. Continuing this example, the controller 430 can be further configured to determine the first intensity sub-signal and the second intensity sub-signal based on the modified intensity signal templates.

The controller 430 can be further configured to determine, based on the set of templates and the set of weight values, first and second intensity sub-signals comprising first and second intensity values corresponding to the first and second diffracted light beams. The controller 430 can be further configured to determine first and second intensity imbalance signals based on the first and second intensity sub-signals. The controller 430 can be further configured to generate a set of corrections (e.g., two corrections (X and Y) per color per polarization) to the measurement signal 429 based on the first and second intensity imbalance signals. For example, the measurement signal 429 can include an X component and a Y component, and the set of corrections can include, but is not limited to, a first correction to the X component of the measurement signal 429 and a second correction to the Y component of the measurement signal 429.

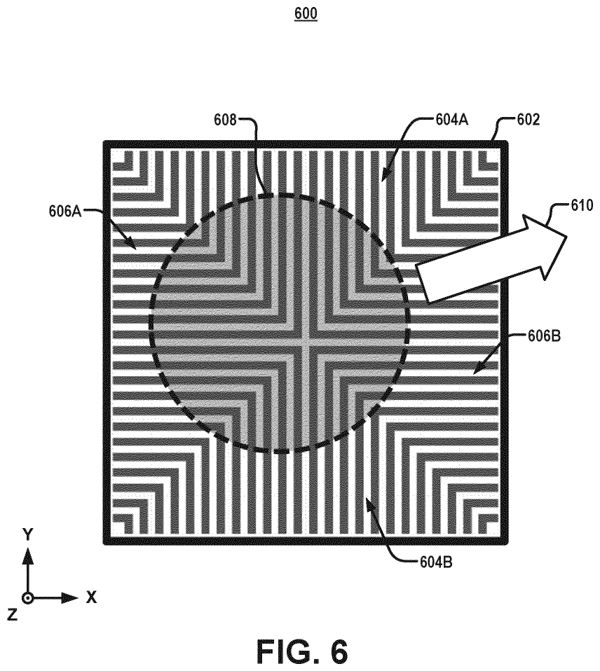

FIG. 5 is a schematic illustration of an example process flow 500 for correcting the detected positions of alignment marks disposed on a substrate according to some aspects of the present disclosure.

At 502, process flow 500 collects combined phase and intensity traces (e.g., raw data) per alignment mark scan. At 504, process flow 500 determines whether both gratings of the scanned alignment mark are monitored simultaneously. If both gratings are monitored, process flow 500 transmits the combined intensity traces to 506 and the combined phase traces to 508. If the gratings are scanned sequentially, process flow 500 proceeds to 520.

At 510, process flow 500 separates the phase trace signal P(λ) per grating using an envelope periodic fit (EPF) or two-dimensional EPF (2DEPF) technique. At 512, process flow 500 feeds a TTF module with the combined phase traces to determine X and Y intensity signal templates I_{X}^{template} and I_{Y}^{template}.

At 514, process flow 500 builds up the equation system by expressing the mixed intensity signals as a weighted sum of the templates. For example, at 514, process flow 500 can express the first combined intensity signal I_{mix,1}=I_{X}⁻+I_{Y}⁺ as a weighted sum of the X and Y intensity signal templates I_{X}^{template} and I_{Y}^{template} determined at 512 as shown in Equation 1:

$$[ \begin{matrix}{I}_{X}^{template} ( {x}_{1} ) & {I}_{Y}^{template} ( {y}_{1} ) \\ {I}_{X}^{template} ( {x}_{1} ) & {I}_{Y}^{template} ( {y}_{1} ) \\ ⋮ & ⋮ \\ {I}_{X}^{template} ( {x}_{n} ) & {I}_{Y}^{template} ( {y}_{n} )\end{matrix} ] [ \begin{matrix}{η}_{X}^{-} \\ {η}_{Y}^{+}\end{matrix} ] = [ \begin{matrix}{I}_{mix , 1} ( {x}_{1} ) \\ {I}_{mix , 1} ( {x}_{2} ) \\ ⋮ \\ {I}_{mix , 1} ( {x}_{n} )\end{matrix} ] \qquad ( 1 )$$

Continuing the example, at 514, process flow 500 can further express the second combined intensity signal I_{mix,2}=I_{X}⁺+I_{Y}⁻ as a weighted sum of the X and Y intensity signal templates template determined at 512 as shown in Equation 2:

$$[ \begin{matrix}{I}_{X}^{template} ( {x}_{1} ) & {I}_{Y}^{template} ( {y}_{1} ) \\ {I}_{X}^{template} ( {x}_{1} ) & {I}_{Y}^{template} ( {y}_{1} ) \\ ⋮ & ⋮ \\ {I}_{X}^{template} ( {x}_{n} ) & {I}_{Y}^{template} ( {y}_{n} )\end{matrix} ] [ \begin{matrix}{η}_{X}^{+} \\ {η}_{Y}^{-}\end{matrix} ] = [ \begin{matrix}{I}_{mix , 2} ( {x}_{1} ) \\ {I}_{mix , 2} ( {x}_{2} ) \\ ⋮ \\ {I}_{mix , 2} ( {x}_{n} )\end{matrix} ] \qquad ( 2 )$$

At 516, process flow 500 uses a least squares fit technique to solve Equations 1 and 2 for the weight values η_{X}⁺, η_{X}⁻, η_{Y}⁺, and η_{Y}⁻. At 518, process flow 500 recovers the intensity signal I(λ) per grating per diffraction order per color. For example, at 518, process flow 500 can determine the intensity sub-signals I_{X}⁺, I_{X}⁻, I_{Y}⁺, and I_{Y}⁻ based on the X and Y intensity signal I_{X}^{template} and I_{Y}^{template} and the determined weight values η_{X}⁺, η_{X}⁻, η_{Y}⁺, and η_{Y}⁻, where I_{X}⁺=η_{X}⁺I_{X}^{template}, I_{X}⁻=η_{X}⁻I_{X}^{template}, I_{Y}⁺=η_{Y}⁺I_{Y}^{template}, and I_{Y}⁻=η_{Y}⁻I_{Y}^{template}.

At 520, process flow 500 calculates the intensity imbalance (e.g., Q values) per grating per color. For example, at 520, process flow 500 can determine the intensity imbalance signals Q_{X} and Q_{Y}, where Q_{X}=(I_{X}⁺−I_{X}⁻)/(I_{X}⁺+I_{X}⁻) and Q_{Y}=(I_{Y}⁺−I_{Y}⁻)/(I_{Y}⁺+I_{Y}⁻). Optionally, after 520, process flow 500 can determine (i) a first correction to an X component of the measurement signal based on the intensity imbalance signal Q_{X} and (ii) a second correction to a Y component of the measurement signal based on the intensity imbalance signal Q_{Y}.

FIG. 6 is a representation of an example combined bidirectional (CB) alignment mark 600 according to some aspects of the present disclosure. As shown in FIG. 6, the CB alignment mark 600 can a perimeter 602 enclosing: a first alignment target 604 (e.g., an X-grating) including a top portion 604A and a bottom portion 604B; and a second alignment target 606 (e.g., a Y-grating) including a left portion 606A and a right portion 606B. In some aspects, the first and second alignment targets 604 and 606 can include alignment mark gratings. In some aspects, a first pattern of the first alignment target 604 can be oriented non-parallel to a second pattern of the second alignment target 606. For example, an angle between patterns of the first and second alignment targets 604 and 606 can be greater than zero degrees and less than 180 degrees. Optionally, as shown in FIG. 6, the pattern of the first alignment target 604 can be oriented perpendicular to the pattern of the second alignment target 606.

As further shown in FIG. 6, an illumination spot 608 can scan the CB alignment mark 600 as indicated by scanning direction 610 (e.g., about zero degrees, about 20 degrees, or any other suitable directional value). Due to the small size of the CB alignment mark 600, the illumination spot 608 can overfill the first alignment target 604 (e.g, the spot size of the illumination spot 608 is incident on one or both of the top portion 604A and the bottom portion 604B of the first alignment target 604), and the illumination spot 608 can further overfill the second alignment target 606 (e.g, the spot size of the illumination spot 608 is further incident on one or both of the left portion 606A and the right portion 606B of the second alignment target 606).

FIGS. 7A and 7B are graphical and pupil representations, respectively, of an example measurement signal 700 resulting from a measurement of the CB alignment mark 600 shown in FIG. 6, according to some aspects of the present disclosure. As shown in FIG. 7A, the measurement signal 700 can include a combined intensity signal 702 and a combined phase signal 704.

As shown in FIG. 7B, because the illumination spot 608 detects signals from both of the first and second alignment targets 604 and 606, and due to the fixed pupil divider 724 of the pupil 722, the signal spots per grating per diffraction order are mixed into two groups and received by the OADB. For example, a first combined intensity signal 734 (I_{mix,1}) can include a mixture of negative first order diffraction (I_{X}⁻) from the first alignment target 604, and positive first order diffraction (I_{Y}⁺) from the second alignment target 606. Similarly, a second combined intensity signal 736 (I_{mix,2}) can include a mixture of positive first order diffraction (I_{X}⁺) from the first alignment target 604, and negative first order diffraction (I_{Y}⁻) from the second alignment target 606.

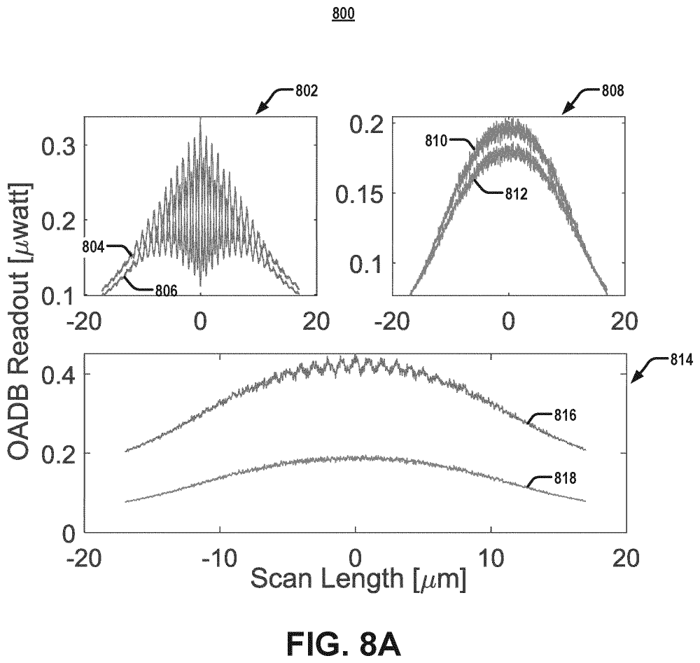

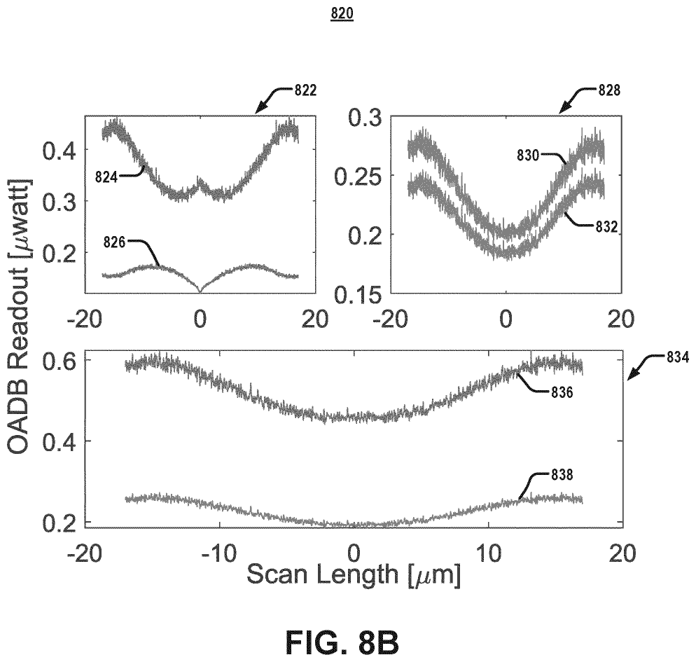

FIGS. 8A and 8B are graphical representations of the intensity and phase components of an example measurement signal according to some aspects of the present disclosure. FIG. 8A is a graphical representation of the intensity and phase components of an example measurement signal 800 resulting from an illumination of the first alignment target 604 shown in FIG. 6, according to some aspects of the present disclosure. As shown in phase graph 802 of FIG. 8A, the measurement signal 800 can include a sum phase signal 804 and a difference phase signal 806. As shown in intensity graph 808, the measurement signal 800 can include a positive first order diffraction intensity signal 810 and a negative first order diffraction intensity signal 812. As shown in graph 814, the combined phase signal 816 (e.g., the sum of the sum phase signal 804 and the difference phase signal 806) can be highly correlated to the combined intensity signal 818 (e.g., the sum of the positive first order diffraction intensity signal 810 and the negative first order diffraction intensity signal 812) and thus can provide the basis for an X intensity template (I_{X}^{template}).

FIG. 8B is a graphical representation of the intensity and phase components of an example measurement signal 820 resulting from an illumination of the second alignment target 606 shown in FIG. 6, according to some aspects of the present disclosure. As shown in phase graph 822 of FIG. 8A, the measurement signal 820 can include a sum phase signal 824 and a difference phase signal 826. As shown in intensity graph 828, the measurement signal 820 can include a positive first order diffraction intensity signal 830 and a negative first order diffraction intensity signal 832. As shown in graph 834, the combined phase signal 836 (e.g., the sum of the sum phase signal 824 and the difference phase signal 826) can be highly correlated to the combined intensity signal 838 (e.g., the sum of the positive first order diffraction intensity signal 830 and the negative first order diffraction intensity signal) 832) and thus can provide the basis for a Y intensity template (I_{Y}^{template}).

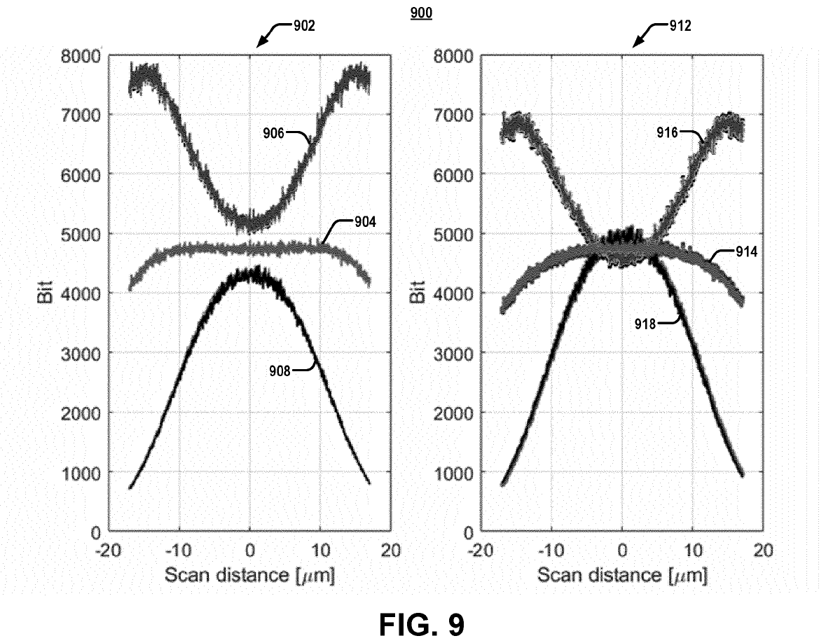

FIG. 9 shows graphical representations of the combined intensity signals of an example measurement signal 900 resulting from an illumination of the CB alignment mark 600 shown in FIG. 6, according to some aspects of the present disclosure.

As shown in graph 902, the measurement signal 900 can include a first combined intensity signal 904 (I_{mix,1}=I_{X}⁻+I_{Y}⁺) measured by a detector, a negative first order diffraction intensity sub-signal 906 (I_{X}⁻=η_{X}⁻I_{X}^{template}) corresponding to diffraction from the first alignment target 604 as computed by a controller, and a positive first order diffraction intensity sub-signal 908 (I_{Y}⁺=η_{Y}⁺I_{Y}^{template}) corresponding to diffraction from the second alignment target 606 as computed by the controller.

As shown in graph 912, the measurement signal 900 can further include a second combined intensity signal 914 (I_{mix,2}=I_{X}⁺+I_{Y}⁻) measured by the detector, a positive first order diffraction intensity sub-signal 916 (I_{X}⁺=η_{X}⁺I_{X}^{template}) corresponding to diffraction from the first alignment target 604 as computed by the controller, and a negative first order diffraction intensity sub-signal 918 (I_{Y}⁻=η_{X}⁻I_{Y}^{template}) corresponding to diffraction from the second alignment target 606 as computed by the controller.

### Example Processes for Correcting the Detected Positions of Alignment Marks

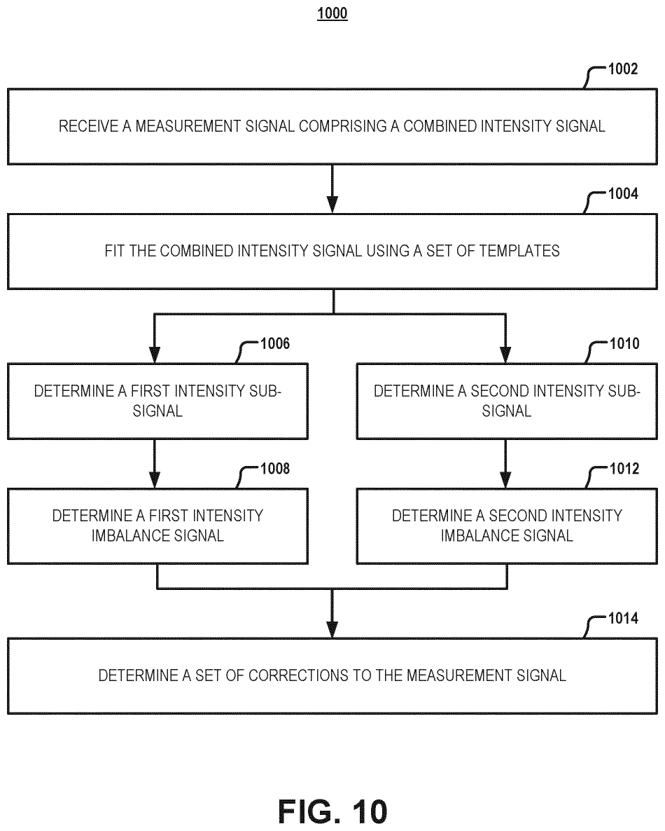

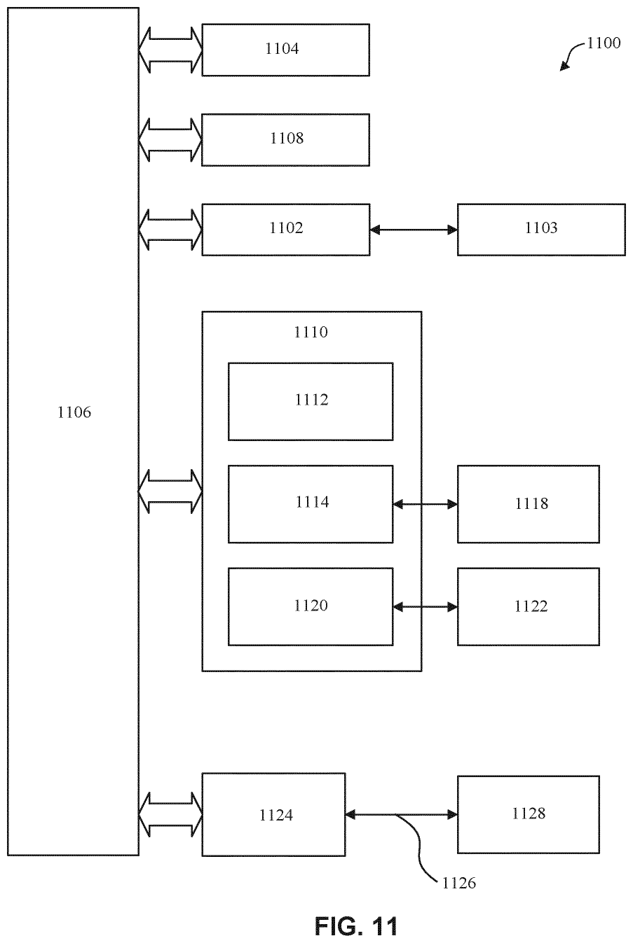

FIG. 10 is an example method 1000 for correcting the detected positions of alignment marks disposed on a substrate according to some aspects of the present disclosure or portion(s) thereof. The operations described with reference to example method 1000 can be performed by, or according to, any of the systems, apparatuses, components, techniques, or combinations thereof described herein, such as those described with reference to FIGS. 1-9 above and FIG. 11 below.

At operation 1002, the method can include receiving (e.g., by controller 430 of metrology system 400) a measurement signal (e.g., measurement signal 429) that includes a combined intensity signal (e.g., combined intensity signal 702, first combined intensity signal 734 (I_{mix,1}=I_{X}⁻+I_{Y}⁺), second combined intensity signal 736 (I_{mix,2}=I_{X}⁺+I_{Y}⁻)) including combined intensity values corresponding to first and second diffracted light beams (e.g., one or more radiation beams 419) diffracted from first and second alignment targets (e.g., plurality of alignment marks 418, first alignment target 604, second alignment target 606), respectively. In some aspects, the second alignment target (e.g., second alignment target 606) can be oriented differently than the first alignment target (e.g., first alignment target 604). In some aspects, the receiving of the measurement signal can be accomplished using suitable mechanical or other methods and include receiving the measurement signal in accordance with any aspect or combination of aspects described with reference to FIGS. 1-9 above and FIG. 11 below.

At operation 1004, the method can include fitting (e.g., by controller 430) the combined intensity signal using a set of templates (e.g., I_{X}^{template}, I_{Y}^{template}) to determine a set of weight values (e.g., η_{X}⁺, η_{X}⁻, η_{Y}⁺, η_{Y}⁻). In some aspects, the fitting of the combined intensity signal can be accomplished using suitable mechanical or other methods and include fitting the combined intensity signal in accordance with any aspect or combination of aspects described with reference to FIGS. 1-9 above and FIG. 11 below.

At operation 1006, the method can include determining (e.g., by controller 430), based on the set of templates and the set of weight values, a first intensity sub-signal (e.g., one of I_{X}⁺, I_{X}⁻, I_{Y}⁺, I_{Y}⁻) including first intensity values corresponding to the first diffracted light beam. Optionally, at operation 1006, the method can include determining (e.g., by controller 430), based on the set of templates and the set of weight values, a first set of intensity sub-signals that includes the first intensity sub-signal, where the first set of intensity sub-signals includes one pair of the intensity sub-signals I_{X}⁺ and I_{X}⁻ or the intensity sub-signals I_{Y}⁺ and I_{Y}⁻. In some aspects, the determining of the first intensity sub-signal can be accomplished using suitable mechanical or other methods and include determining the first intensity sub-signal in accordance with any aspect or combination of aspects described with reference to FIGS. 1-9 above and FIG. 11 below.

At operation 1008, the method can include determining (e.g., by controller 430) a first intensity imbalance signal (e.g., one of Q_{X}, Q_{Y}) based on the first intensity sub-signal. In some aspects, the determining of the first intensity imbalance signal can be accomplished using suitable mechanical or other methods and include determining the first intensity imbalance signal in accordance with any aspect or combination of aspects described with reference to FIGS. 1-9 above and FIG. 11 below.

At operation 1010, the method can include determining (e.g., by controller 430), based on the fit combined intensity signal, a second intensity sub-signal (e.g., another of I_{X}⁺, I_{X}⁻, I_{Y}⁺, I_{Y}⁻) comprising second intensity values corresponding to the second diffracted light beam. Optionally, at operation 1010, the method can include determining (e.g., by controller 430), based on the set of templates and the set of weight values, a second set of intensity sub-signals that includes the second intensity sub-signal, where the second set of intensity sub-signals includes the other pair of the intensity sub-signals I_{X}⁺ and I_{X}⁻ or the intensity sub-signals I_{Y}⁺ and I_{Y}⁻. In some aspects, the determining of the second intensity sub-signal can be accomplished using suitable mechanical or other methods and include determining the second intensity sub-signal in accordance with any aspect or combination of aspects described with reference to FIGS. 1-9 above and FIG. 11 below.

At operation 1012, the method can include determining (e.g., by controller 430) a second intensity imbalance signal (e.g., the other of Q_{X}, Q_{Y}) based on the second intensity sub-signal. In some aspects, the determining of the second intensity imbalance signal can be accomplished using suitable mechanical or other methods and include determining the second intensity imbalance signal in accordance with any aspect or combination of aspects described with reference to FIGS. 1-9 above and FIG. 11 below.

At operation 1014, the method can include determining (e.g., by controller 430) a set of corrections (e.g., two corrections (X and Y) per color per polarization) to the measurement signal based on the first and second intensity imbalance signals. For example, the set of corrections can include, but is not limited to, a first correction to an X component of the measurement signal and a second correction to a Y component of the measurement signal. In some aspects, the “correct” position for alignment can be where the alignment mark would appear if no alignment mark asymmetry were present. In some aspects, the correction can be based on the use of combining the signals of several colors and polarizations (e.g., determining the correction by combining all, or the most relevant, detectable colors). In some aspects, the determining of the set of corrections can be accomplished using suitable mechanical or other methods and include determining the set of corrections in accordance with any aspect or combination of aspects described with reference to FIGS. 1-9 above and FIG. 11 below.

### Example Computing System

Aspects of the disclosure can be implemented in hardware, firmware, software, or any combination thereof. Aspects of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions, and combinations thereof can be described herein as performing certain actions. However, it should be appreciated that such descriptions are merely for convenience and that such actions in fact result from computing devices, processors, controllers, or other devices executing the firmware, software, routines, instructions, or combinations thereof and, in doing so, causing actuators or other devices (e.g., servo motors, robotic devices) to interact with the physical world.

Various aspects can be implemented, for example, using one or more computing systems, such as example computing system 1100 shown in FIG. 11. Example computing system 1100 can be a specialized computer capable of performing the functions described herein such as: the metrology system 400 described with reference to FIG. 4; any other suitable system, sub-system, or component; or any combination thereof. Example computing system 1100 can include one or more processors (also called central processing units, or CPUs), such as a processor 1104. Processor 1104 is connected to a communication infrastructure 1106 (e.g., a bus). Example computing system 1100 can also include user input/output device(s) 1103, such as monitors, keyboards, pointing devices, etc., that communicate with communication infrastructure 1106 through user input/output interface(s) 1102. Example computing system 1100 can also include a main memory 1108 (e.g., one or more primary storage devices), such as random access memory (RAM). Main memory 1108 can include one or more levels of cache. Main memory 1108 has stored therein control logic (e.g., computer software) and/or data.

Example computing system 1100 can also include a secondary memory 1110 (e.g., one or more secondary storage devices). Secondary memory 1110 can include, for example, a hard disk drive 1112 and/or a removable storage drive 1114. Removable storage drive 1114 can be a floppy disk drive, a magnetic tape drive, a compact disk drive, an optical storage device, tape backup device, and/or any other storage device/drive.

Removable storage drive 1114 can interact with a removable storage unit 1118. Removable storage unit 1118 includes a computer usable or readable storage device having stored thereon computer software (control logic) and/or data. Removable storage unit 1118 can be a floppy disk, magnetic tape, compact disk, DVD, optical storage disk, and/or any other computer data storage device. Removable storage drive 1114 reads from and/or writes to removable storage unit 1118.

According to some aspects, secondary memory 1110 can include other means, instrumentalities or other approaches for allowing computer programs and/or other instructions and/or data to be accessed by example computing system 1100. Such means, instrumentalities or other approaches can include, for example, a removable storage unit 1122 and an interface 1120. Examples of the removable storage unit 1122 and the interface 1120 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Example computing system 1100 can further include a communications interface 1124 (e.g., one or more network interfaces). Communications interface 1124 enables example computing system 1100 to communicate and interact with any combination of remote devices, remote networks, remote entities, etc. (individually and collectively referred to as remote devices 1128). For example, communications interface 1124 can allow example computing system 1100 to communicate with remote devices 1128 over communications path 1126, which can be wired and/or wireless, and which can include any combination of LANs, WANs, the Internet, etc. Control logic, data, or both can be transmitted to and from example computing system 1100 via communications path 1126.

The operations in the preceding aspects of the present disclosure can be implemented in a wide variety of configurations and architectures. Therefore, some or all of the operations in the preceding aspects can be performed in hardware, in software or both. In some aspects, a tangible, non-transitory apparatus or article of manufacture includes a tangible, non-transitory computer useable or readable medium having control logic (software) stored thereon is also referred to herein as a computer program product or program storage device. This includes, but is not limited to, example computing system 1100, main memory 1108, secondary memory 1110 and removable storage units 1118 and 1122, as well as tangible articles of manufacture embodying any combination of the foregoing. Such control logic, when executed by one or more data processing devices (such as example computing system 1100), causes such data processing devices to operate as described herein.

Based on the teachings contained in this disclosure, it will be apparent to persons skilled in the relevant art(s) how to make and use aspects of the disclosure using data processing devices, computer systems and/or computer architectures other than that shown in FIG. 11. In particular, aspects of the disclosure can operate with software, hardware, and/or operating system implementations other than those described herein.

The embodiments may further be described using the following clauses:
1. A metrology system, comprising:
   an illumination system configured to generate and direct light to be diffracted from first and second alignment targets, the second alignment target being oriented differently than the first alignment target;
   a detection system configured to receive first and second diffracted light beams diffracted from respective ones of the first and second alignment targets and to generate a measurement signal therefrom, wherein the measurement signal comprises a combined intensity signal comprising combined intensity values corresponding to the first and second diffracted light beams diffracted from the respective ones of the first and second alignment targets; and
   a controller configured to:
      fit the combined intensity signal using a set of templates to determine a set of weight values,
      determine, based on the set of templates and the set of weight values, first and second intensity sub-signals comprising first and second intensity values corresponding to the first and second diffracted light beams,
      determine first and second intensity imbalance signals based on the first and second intensity sub-signals, and
      determine a set of corrections to the measurement signal based on the first and second intensity imbalance signals.
2. The metrology system of clause 1, wherein the detection system comprises:
   a detector configured to:
   receive the first and second diffracted light beams, and
      generate the combined intensity signal.
3. The metrology system of clause 1, wherein:
   a spot size of the light at least partially overfills the first alignment target;
      the spot size of the light at least partially overfills the second alignment target; and
      the detection system is configured to:
         detect the first and second diffracted light beams simultaneously; and
      generate the combined intensity signal based on the simultaneously-detected first and second diffracted light beams.
4. The metrology system of clause 1, where the first and second alignment targets comprise alignment mark gratings.
5. The metrology system of clause 1, wherein the first and second alignment targets comprise a combined bidirectional alignment mark.
6. The metrology system of clause 1, wherein a first pattern of the first alignment target is oriented non-parallel to a second pattern of the second alignment target.
7. The metrology system of clause 1, wherein:
   the measurement signal further comprises a combined phase signal comprising combined phase values corresponding to the first and second diffracted light beams; and
   the controller is configured to generate the set of templates based on the combined phase signal.
8. The metrology system of clause 1, wherein the controller is configured to generate the set of templates based on a simulation.
9. The metrology system of clause 1, wherein:
   the set of templates comprises first and second subsets of templates corresponding to respective ones of the first and second alignment targets; and
   the controller is configured to model the combined intensity signal as a weighted sum of the first and second subsets of templates.
10. The metrology system of clause 1, wherein:
   the set of templates comprises intensity signal templates;
   the controller is further configured to:
   determine the set of templates using a trace template fit (TTF) machine learning model trained on measurements associated with alignment marks by a process comprising:
      fitting the intensity signal templates on each of the measurements, and refitting the fitted intensity signal templates for each of the alignment marks to
   generate modified intensity signal templates; and
   determine the first intensity sub-signal and the second intensity sub-signal based on the modified intensity signal templates.
11. The metrology system of clause 1, wherein the light generated by the illumination system comprises a plurality of wavelengths or a plurality of polarization phases.
12. A lithographic apparatus, comprising:
   an illumination system configured to illuminate a pattern of a patterning device;
   a projection system configured to project an image of the pattern onto a target portion of a substrate; and
   a metrology system comprising:
      an illumination subsystem configured to generate and direct light to be diffracted from first and second alignment targets, the second alignment target being oriented differently than the first alignment target;
      a detection system configured to receive first and second diffracted light beams diffracted from respective ones of the first and second alignment targets and to generate a measurement signal therefrom, wherein the measurement signal comprises a combined intensity signal comprising combined intensity values corresponding to the first and second diffracted light beams diffracted from the respective ones of the first and second alignment targets; and
      a controller configured to:
         fit the combined intensity signal using a set of templates to determine a set of weight values,
         determine, based on the set of templates and the set of weight values, first and second intensity sub-signals comprising first and second intensity values corresponding to the first and second diffracted light beams,
         determine first and second intensity imbalance signals based on the first and second intensity sub-signals, and
         determine a set of corrections to the measurement signal based on the first and second intensity imbalance signals.
13. The lithographic apparatus of clause 12, wherein:
   a spot size of the light at least partially overfills the first alignment target;
   the spot size of the light at least partially overfills the second alignment target; and
   the detection system is configured to:
      detect the first and second diffracted light beams simultaneously; and
      generate the combined intensity signal based on the simultaneously-detected first and second diffracted light beams.
14. The lithographic apparatus of clause 12, wherein the first and second alignment targets comprise a combined bidirectional alignment mark.
15. The lithographic apparatus of clause 12, wherein a first pattern of the first alignment target is oriented non-parallel to a second pattern of the second alignment target.
16. The lithographic apparatus of clause 12, wherein:
   the measurement signal further comprises a combined phase signal comprising combined phase values corresponding to the first and second diffracted light beams; and
   the controller is configured to generate the set of templates based on the combined phase signal.
17. A method, comprising:
   receiving a measurement signal, wherein the measurement signal comprises a combined intensity signal comprising combined intensity values corresponding to first and second diffracted light beams diffracted from first and second alignment targets, the second alignment target being oriented differently than the first alignment target;
   fitting the combined intensity signal using a set of templates to determine a set of weight values;
   determining, based on the set of templates and the set of weight values, first and second intensity sub-signals comprising first and second intensity values corresponding to the first and second diffracted light beams;
   determining first and second intensity imbalance signals based on the first and second intensity sub-signals; and
   determining a set of corrections to the measurement signal based on the first and second intensity imbalance signals.
18. The method of clause 17, wherein:
   a spot size of the light at least partially overfills the first alignment target;
   the spot size of the light at least partially overfills the second alignment target; and
   the method further comprises:
      detecting the first and second diffracted light beams simultaneously; and
   generating the combined intensity signal based on the simultaneously-detected first and second diffracted light beams.
19. The method of clause 17, wherein a first pattern of the first alignment target is oriented non-parallel to a second pattern of the second alignment target.
20. The method of clause 17, wherein:
   the measurement signal further comprises a combined phase signal comprising combined phase values corresponding to the first and second diffracted light beams; and
   the method further comprises generating the set of templates based on the combined phase signal.

Although specific reference may be made in this text to the use of lithographic apparatus in the manufacture of ICs, it should be understood that the lithographic apparatuses described herein can have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein can be processed, before or after exposure, in for example a track unit (a tool that applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself can be patterned and materials added on top of it can also be patterned, or can remain without patterning.

The examples disclosed herein are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific aspects of the disclosure have been described above, it will be appreciated that the aspects can be practiced otherwise than as described. The description is not intended to limit the embodiments of the disclosure.

It is to be appreciated that the Detailed Description section, and not the Background, Summary, and Abstract sections, is intended to be used to interpret the claims. The Summary and Abstract sections may set forth one or more but not all example embodiments as contemplated by the inventor(s), and thus, are not intended to limit the present embodiments and the appended claims in any way.

Some aspects of the disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects of the disclosure will so fully reveal the general nature of the aspects that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein.

The breadth and scope of the present disclosure should not be limited by any of the above-described example aspects or embodiments, but should be defined only in accordance with the following claims and their equivalents.

1. A metrology system, comprising:
an illumination system configured to generate and direct light to be diffracted from first and second alignment targets, the second alignment target being oriented differently than the first alignment target;
a detection system configured to receive first and second diffracted light beams diffracted from respective ones of the first and second alignment targets and to generate a measurement signal therefrom, wherein the measurement signal comprises a combined intensity signal comprising combined intensity values corresponding to the first and second diffracted light beams diffracted from the respective ones of the first and second alignment targets; and
a controller configured to:
fit the combined intensity signal using a set of templates to determine a set of weight values,
determine, based on the set of templates and the set of weight values, first and second intensity sub-signals comprising first and second intensity values corresponding to the first and second diffracted light beams,
determine first and second intensity imbalance signals based on the first and second intensity sub-signals, and
determine a set of corrections to the measurement signal based on the first and second intensity imbalance signals.

2. The metrology system of claim 1, wherein the detection system comprises:
a detector configured to:
receive the first and second diffracted light beams, and
generate the combined intensity signal.

3. The metrology system of claim 1, wherein:
a spot size of the light at least partially overfills the first alignment target;
the spot size of the light at least partially overfills the second alignment target; and
the detection system is configured to:
detect the first and second diffracted light beams simultaneously; and
generate the combined intensity signal based on the simultaneously-detected first and second diffracted light beams.

4. The metrology system of claim 1, where the first and second alignment targets comprise alignment mark gratings.

5. The metrology system of claim 1, wherein the first and second alignment targets comprise a combined bidirectional alignment mark.

6. The metrology system of claim 1, wherein a first pattern of the first alignment target is oriented non-parallel to a second pattern of the second alignment target.

7. The metrology system of claim 1, wherein:
the measurement signal further comprises a combined phase signal comprising combined phase values corresponding to the first and second diffracted light beams; and
the controller is configured to generate the set of templates based on the combined phase signal.

8. The metrology system of claim 1, wherein the controller is configured to generate the set of templates based on a simulation.

9. The metrology system of claim 1, wherein:
the set of templates comprises first and second subsets of templates corresponding to respective ones of the first and second alignment targets; and
the controller is configured to model the combined intensity signal as a weighted sum of the first and second subsets of templates.

10. The metrology system of claim 1, wherein:
the set of templates comprises intensity signal templates;
the controller is further configured to:
determine the set of templates using a trace template fit (TTF) machine learning model trained on measurements associated with alignment marks by a process comprising:
fitting the intensity signal templates on each of the measurements, and
refitting the fitted intensity signal templates for each of the alignment marks to generate modified intensity signal templates; and
determine the first intensity sub-signal and the second intensity sub-signal based on the modified intensity signal templates.

11. The metrology system of claim 1, wherein the light generated by the illumination system comprises a plurality of wavelengths or a plurality of polarization phases.

12. A lithographic apparatus, comprising:
an illumination system configured to illuminate a pattern of a patterning device;
a projection system configured to project an image of the pattern onto a target portion of a substrate; and
a metrology system comprising:
an illumination subsystem configured to generate and direct light to be diffracted from first and second alignment targets, the second alignment target being oriented differently than the first alignment target;
a detection system configured to receive first and second diffracted light beams diffracted from respective ones of the first and second alignment targets and to generate a measurement signal therefrom, wherein the measurement signal comprises a combined intensity signal comprising combined intensity values corresponding to the first and second diffracted light beams diffracted from the respective ones of the first and second alignment targets; and
a controller configured to:
fit the combined intensity signal using a set of templates to determine a set of weight values,
determine, based on the set of templates and the set of weight values, first and second intensity sub-signals comprising first and second intensity values corresponding to the first and second diffracted light beams,
determine first and second intensity imbalance signals based on the first and second intensity sub-signals, and
determine a set of corrections to the measurement signal based on the first and second intensity imbalance signals.

13. The lithographic apparatus of claim 12, wherein:
a spot size of the light at least partially overfills the first alignment target;
the spot size of the light at least partially overfills the second alignment target; and
the detection system is configured to:
detect the first and second diffracted light beams simultaneously; and
generate the combined intensity signal based on the simultaneously-detected first and second diffracted light beams.

14. The lithographic apparatus of claim 12, wherein the first and second alignment targets comprise a combined bidirectional alignment mark.

15. The lithographic apparatus of claim 12, wherein a first pattern of the first alignment target is oriented non-parallel to a second pattern of the second alignment target.

16. The lithographic apparatus of claim 12, wherein:
the measurement signal further comprises a combined phase signal comprising combined phase values corresponding to the first and second diffracted light beams; and
the controller is configured to generate the set of templates based on the combined phase signal.

17. A method, comprising:
receiving a measurement signal, wherein the measurement signal comprises a combined intensity signal comprising combined intensity values corresponding to first and second diffracted light beams diffracted from first and second alignment targets, the second alignment target being oriented differently than the first alignment target;
fitting the combined intensity signal using a set of templates to determine a set of weight values;
determining, based on the set of templates and the set of weight values, first and second intensity sub-signals comprising first and second intensity values corresponding to the first and second diffracted light beams;
determining first and second intensity imbalance signals based on the first and second intensity sub-signals; and
determining a set of corrections to the measurement signal based on the first and second intensity imbalance signals.

18. The method of claim 17, wherein:
a spot size of the light at least partially overfills the first alignment target;
the spot size of the light at least partially overfills the second alignment target; and
the method further comprises:
detecting the first and second diffracted light beams simultaneously; and
generating the combined intensity signal based on the simultaneously-detected first and second diffracted light beams.

19. The method of claim 17, wherein a first pattern of the first alignment target is oriented non-parallel to a second pattern of the second alignment target.

20. The method of claim 17, wherein:
the measurement signal further comprises a combined phase signal comprising combined phase values corresponding to the first and second diffracted light beams; and
the method further comprises generating the set of templates based on the combined phase signal.
